(19) United States
(12) Patent Application Publication
(10) Pub. No.: US 2007/0128552 A1
(43) Pub. Date: Jun. 7, 2007

(54) Manufacturing method of pattern formed body and pattern formed body manufacturing apparatus

(76) Inventors: Takashi Sawada, Tokyo (JP); Kaori Yamashita, Tokyo (JP); Hironori Kobayashi, Tokyo (JP)

Correspondence Address: LADAS & PARRY LLP, 224 SOUTH MICHIGAN AVENUE, SUITE 1600, CHICAGO, IL, 60604, US

(21) Appl. No.: 11/526,973

(22) Filed: Sep. 26, 2006

(30) Foreign Application Priority Data
Sep. 29, 2005 (JP) 2005-285484

(51) Int. Cl. G03B 27/42; G03F 7/00

(52) U.S. Cl. 430/311; 355/53

(57) ABSTRACT

A main object of the invention is to provide a a manufacturing method of a plurality of pattern formed bodies which makes it possible that even if the pattern formed bodies are continuously manufactured, their property varied patterns are each made into a target pattern form with high precision; and a pattern formed body manufacturing apparatus used in the manufacturing method. To achieve the object, the invention provides a manufacturing method of a plurality of pattern formed bodies comprising a pattern forming step and a foreign matter removing step, wherein the pattern forming step is a step of radiating vacuum-ultraviolet light through a photomask to a pattern forming substrate, varying a surface property by the vacuum-ultraviolet light, and forming a property varied pattern with the property varied on a surface of the pattern forming substrate to form a pattern formed body; the pattern forming step is repeated plural times to manufacture a plurality of the pattern formed bodies; and the foreign matter removing step is a step of removing a foreign matter deposited to the photomask performed between the repeated pattern forming steps.

### BACKGROUND OF THE INVENTION

1. Field of the Invention

The present invention relates to a manufacturing method of a pattern formed body which has a surface property varied in a pattern form and is used in the manufacture of, for example, a color filter; and a pattern formed body manufacturing apparatus used in the manufacturing method.

2. Description of the Related Art

Conventionally, various methods have been suggested as a manufacturing method of a plurality of pattern formed bodies in which designs, images, characters, circuits or other various patterns are formed on a base material. For example, there are also used lithographic printing, offset printing, a printing method of using a heat-mode recording material to produce a lithographic original master, and other methods. Moreover, there is known, for example, a manufacturing method of a pattern formed body, comprising the step of radiating light patternwise to a photoresist layer coated on a base material, developing the photoresist, and then etching the photoresist, or the step of using a material having functionality as a photoresist, and exposing the photoresist to light to form a target pattern directly.

However, the above-mentioned printing methods have: a problem that at the time of manufacturing a highly precise pattern formed body, which is used in such as a color filter, only a low location accuracy is attained; and other problems. Thus, it is difficult to use the methods. The above-mentioned photolithography has: a problem that it is necessary to dispose of waste liquid since a photoresist is used and the photoresist is required to be developed with a developing liquid and be etched after exposed to light; and other problems. When a material having functionality is used as the photoresist, there is caused a problem that this material is deteriorated with an alkali solution or the like that is used in development.

Thus, there is suggested a manufacturing method of a pattern formed body, comprising the step of radiating vacuum-ultraviolet light patternwise through a photomask to a pattern forming substrate having a base material and an organic molecule membrane formed on the base material and made of an organic material, thereby decomposing and removing the organic molecule membrane to form a pattern (see Japanese Patent Application Laid-Open (JP-A) No. 2001-324816). According to this method, a pattern formed body can be manufactured without using any photoresist; therefore, the pattern formed body can easily be manufactured without any developing solution or the like.

Such formation of a pattern by use of vacuum-ultraviolet light is attained by decomposition and removal of the organic molecule membrane by action of the vacuum-ultraviolet light. Specifically, when vacuum-ultraviolet light is radiated thereto, molecular bonds of an organic material of the organic molecule membrane are cleaved by action of the vacuum-ultraviolet light; or in the presence of oxygen, oxygen atom radicals generated by excitation of the oxygen act onto the organic material, so that the organic material of the organic molecule membrane becomes a decomposition product and then this product is volatilized and removed from the pattern forming substrate so as to form a pattern.

However, in the case of manufacturing pattern formed bodies continuously by radiation of vacuum-ultraviolet light through a photomask as described above, a decomposition product and so on which are generated on a used pattern forming substrate deposit onto the photomask. This foreign matter hinders the action of the above-mentioned oxygen atom radicals. Conversely, the foreign matter may contribute to a change in the property of the pattern forming substrate. Thus, there remains a problem that patterns having a uniform line width are not easily formed on the pattern forming substrate.

### SUMMARY OF THE INVENTION

Thus, it is desired to provide a manufacturing method of a plurality of pattern formed bodies which makes it possible that even if the pattern formed bodies are continuously manufactured, their property varied patterns are each made into a target pattern form with high precision; and a pattern formed body manufacturing apparatus used in the manufacturing method.

The present invention provides a manufacturing method of a plurality of pattern formed bodies comprising a pattern forming step and a foreign matter removing step, wherein the pattern forming step is a step of radiating vacuum-ultraviolet light through a photomask to a pattern forming substrate, varying a surface property by the vacuum-ultraviolet light, and forming a property varied pattern with the property varied on a surface of the pattern forming substrate to form a pattern formed body; the pattern forming step is repeated plural times to manufacture a plurality of the pattern formed bodies; and the foreign matter removing step is a step of removing a foreign matter deposited to the photomask performed between the repeated pattern forming steps.

According to the invention, between the plural pattern forming steps, the foreign matter removing step of removing the foreign matter deposited to the photomask is performed; therefore, it is possible to prevent the foreign matter deposited to the photomask from producing an effect on the formation of the property varied pattern. According to the invention, therefore, even if the pattern forming step is repeated, properties of individual pattern forming substrates can be varied into a target pattern form. As a result, plural high-quality pattern formed bodies can be manufactured.

The invention can further comprise a leaving period deciding step of deciding a period when the photomask is to be left as it is, and the foreign matter removing step may be a step of leaving the photomask as it is in the period decided in the leaving period deciding step to remove the foreign matter deposited to the photomask. When the photomask is left as it is in a certain period or a longer period, the foreign matter deposited to the photomask surface can be removed.

In the invention, the foreign matter removing step may be any one of the following steps: a step of suctioning and removing the foreign matter deposited to the photomask surface; a step of removing the foreign matter deposited to the photomask surface by wind pressure; a step of washing the foreign matter deposited to the photomask surface with a liquid; a step of removing the foreign matter deposited to the photomask surface by action of water vapor; a step of adsorbing and removing the foreign matter deposited to the photomask surface by means of an adsorbing plate; and a step of radiating thermal energy to the photomask surface, thereby removing the foreign matter depositing to the photomask. According to the method comprising any one of these steps, the foreign matter deposited to the photomask surface can be effectively released.

In the Invention, the foreign matter removing step may be any one of the following steps: a step of radiating plasma to the photomask, thereby removing the foreign matter deposited to the photomask surface; a step of radiating an electron beam to the photomask, thereby removing the foreign matter deposited to the photomask surface; a step of radiating positively- and/or negatively-charged ions to the photomask, thereby removing the foreign matter deposited to the photomask surface; and a step of preparing a photocatalyst containing layer side substrate having a base material and a photocatalyst containing layer formed on the base material and comprising at least a photocatalyst, arranging the surface of the photomask onto which the foreign matter deposits and the photocatalyst containing layer of the photocatalyst containing layer side substrate to oppose to each other, and radiating energy to the photocatalyst containing layer, thereby removing the foreign matter deposited to the photomask surface. According to the method comprising any one of these steps, the foreign matter deposited to the photomask surface can be effectively decomposed and removed.

The invention further provides a pattern formed body manufacturing apparatus used at the time of manufacturing a plurality of pattern formed bodies, wherein the pattern formed bodies are manufactured by repeating plural times a pattern forming step which is a step of radiating vacuum-ultraviolet light through a photomask to a pattern forming substrate, varying a surface property by the vacuum-ultraviolet light, and forming a property varied pattern with the property varied on a surface of the pattern forming substrate to form a pattern formed body; and the apparatus comprises: a pattern forming substrate supporting section for supporting the pattern forming substrate, a photomask supporting section for supporting the photomask to be oppose to the pattern forming substrate, a vacuum-ultraviolet light radiating section for radiating the vacuum-ultraviolet light to the pattern forming substrate, and foreign matter removing means for removing a foreign matter deposited to the photomask.

Since the pattern formed body manufacturing apparatus of the invention has the above-mentioned foreign matter removing means, the foreign matter deposited to the photomask surface can be removed between the plural pattern forming steps. Accordingly, the use of the pattern formed body manufacturing apparatus of the invention makes the following possible: even if radiation of vacuum-ultraviolet light through the photomask is performed, thereby varying properties of pattern forming substrates patternwise so as to manufacture pattern formed bodies continuously, the foreign matter deposited to the photomask is prevented from producing an effect on the formation of the property varied patterns. As a result, plural pattern formed bodies in which their property varied patterns are made into a target pattern form with high precision can be manufactured.

In the invention, the foreign matter removing means may be any one of the following: suctioning means for suctioning the foreign matter deposited to the photomask; gas blowing means for removing the foreign matter by wind pressure; washing means for washing the photomask with a liquid; water vapor acting means for removing the foreign matter deposited to the photomask by action of water vapor; adsorbing means for contacting an adsorbing plate with the photomask to remove the foreign matter; thermal energy radiating means for radiating thermal energy to the photomask; ion radiating means for radiating positively- and/or negatively-charged ions to the photomask; and photocatalyst acting means for removing the foreign matter deposited to the photomask by action of a photocatalyst accompanying energy radiation. When each of these means is fitted to the apparatus, the foreign matter deposited to the photomask can be effectively removed.

According to the invention, patterning can be attained by use of a photomask from which any foreign matter has been removed. Thus, the invention produces an advantageous effect that pattern formed bodies in which their properties are varied into a target pattern form with high precision can be manufactured.

### BRIEF DESCRIPTION OF THE DRAWINGS

FIGS. 1A and 1B are each a process drawing illustrating an example of a manufacturing method of a pattern formed body according to the invention;

FIGS. 2A and 2B are each a view for explaining a pattern formed body manufacturing apparatus of the invention;

FIG. 3 is a schematic sectional view illustrating an example of the pattern formed body manufacturing apparatus of the invention;

FIG. 4 is a schematic sectional view illustrating another example of the pattern formed body manufacturing apparatus of the invention;

FIG. 5 is a schematic sectional view illustrating still another example of the pattern formed body manufacturing apparatus of the invention;

FIG. 6 is a schematic sectional view illustrating a further example of the pattern formed body manufacturing apparatus of the invention; and

FIG. 7 is a schematic sectional view illustrating an additional example of the pattern formed body manufacturing apparatus of the invention.

### DESCRIPTION OF THE PREFERRED EMBODIMENTS

The present invention is concerned with a manufacturing method of a pattern formed body which has a surface property varied in a pattern form and is used in the manufacture of, for example, color filter; and a pattern formed body manufacturing apparatus used in the manufacturing method. The method and the apparatus will be separately described hereinafter.

A. Manufacturing Method of a Plurality of Pattern Formed Bodies

First, a manufacturing method of a plurality of pattern formed bodies will be explained. The manufacturing method of a plurality of pattern formed bodies of the invention comprising a pattern forming step and a foreign matter removing step, wherein the pattern forming step is a step of radiating vacuum-ultraviolet light through a photomask to a pattern forming substrate, varying a surface property by the vacuum-ultraviolet light, and forming a property varied pattern with the property varied on a surface of the pattern forming substrate to form a pattern formed body; the pattern forming step is repeated plural times to manufacture a plurality of the pattern formed bodies; and the foreign matter removing step is a step of removing a foreign matter deposited to the photomask performed between the repeated pattern forming steps.

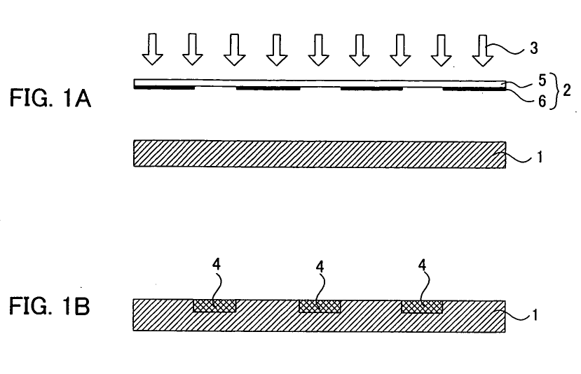

As illustrated in, for example, FIGS. 1A and 1B, the manufacturing method of a plurality of pattern formed bodies according to the invention is a method of performing a pattern forming step plural times, this step being a step of radiating vacuum-ultraviolet light 3 through a photomask 2 to a pattern forming substrate 1 having a surface the property of which is varied by the vacuum-ultraviolet light (FIG. 1A), thereby forming a property varied pattern 4, in which the property is varied, patternwise on the surface of the pattern forming substrate 1 (FIG. 1B), so as to manufacture the plural pattern formed bodies, in which a foreign matter removing step of removing a foreign matter deposited to the photomask is performed between the plural pattern forming steps.

In the case of radiating, in the prior art, vacuum-ultraviolet light through the photomask to a pattern forming substrate, thereby patterning the pattern forming substrate, a decomposition product or the like which is generated on the pattern forming substrate may vaporize so as to deposit to the photomask, which is arranged to be opposed to the pattern forming substrate. Thus, when other pattern forming substrates are continuously patterned, this foreign matter deposited to the photomask may contribute to a change in the property of the pattern forming substrate, or the foreign matter may hinder the action of oxygen atom radicals generated by action of the vacuum-ultraviolet light. Accordingly, when plural pattern formed bodies are continuously manufactured, there arises a problem that it is difficult to make property varied patterns formed on the pattern formed bodies into the form of a target pattern, that is, to make lines of these property varied patterns uniform (i.e., equal to each other).

In the invention, however, between the plural pattern forming steps, the foreign matter removing step of removing the foreign matter deposited to the photomask is performed using the photomask; therefore, when any one of the pattern forming steps is performed, it is possible to prevent the foreign matter deposited to the photomask from changing the line width of the property varied pattern, or the like. Accordingly, even if pattern formed bodies are continuously manufactured, their property varied patterns can be formed into a target pattern form with high precision. In this way, the invention makes it possible to manufacture stably plural pattern formed bodies capable of forming various functional parts along their property varied patterns.

The following will describe each of the steps of the manufacturing method of a plurality of pattern formed bodies according to the invention.

1. Foreign Matter Removing Step

First, the foreign matter removing step in the invention is described herein. The foreign matter removing step is a step per formed between the plural pattern forming steps, and is a step for removing the foreign matter deposited to the photomask. The wording “between the plural pattern forming steps” means, without any limitation, the individual interval between the pattern forming step(s) and the pattern forming step(s). Thus, for example, the present step may be performed whenever any one of the pattern forming steps is finished, or may be performed whenever plural ones of the pattern forming steps are finished.

The following will describe, in detail, a method for removing the foreign matter from the photomask in the present step, and the photomask from which the foreign matter is removed.

(Method for Removing the Foreign Matter from the Photomask)

First, the method for removing the foreign matter deposited to the photomask in the present step is described herein. In the invention, this method is not particularly limited as long as the method is a method capable of removing the foreign matter. Examples of this method include a method of leaving the photomask as it is in a predetermined period, a method of using gas to remove the foreign matter from the photomask, a method of using a liquid to remove the foreign matter from the photomask, a method of using a solid material to remove the foreign matter from the photomask, and a method of using energy to remove the foreign matter from the photomask. The present step may be a step in which any one of these methods is performed, or a step in which two or more of these methods are combined. From these methods, appropriate one is selected in accordance with the kind of the foreign matter deposited to the photomask, or the like.

Each of the exemplified methods will be described in detail hereinafter.

(1) Method of Leaving the Photomask as it is in a Predetermined Period

First, the method of leaving the photomask to remove a foreign matter from the photomask as it is in a predetermined period in the present step is described herein. The word “leaving” means that the photomask is allowed to stand still. Thus, the present method may be a method of allowing the photomask to stand still in a pattern formed body manufacturing apparatus for manufacturing a pattern formed body, or a method of allowing the photomask to stand still after the photomask is taken out from the pattern formed body manufacturing apparatus. The environment in which the photomask is left as it is, is not particularly limited, and the temperature, humidity, pressure and other factors of the environment are appropriately selected in accordance with the kind of the foreign matter.

The time until the foreign matter is removed from the photomask is varied in accordance with the kind of the foreign matter, or the like. Thus, the period when the foreign matter is to be left as it is, is decided in a leaving period deciding step which is performed before the present step.

The leaving period deciding step is a step for deciding a period when the photomask is to be left as it is in the above-mentioned foreign matter removing step, and can be performed in the way described below. First, under the same conditions as in the pattern forming steps, which will be detailed later, a photomask which has not yet been used is used to form a property varied pattern on a pattern forming substrate to produce a pattern formed body. Thereafter, the produced pattern formed body is taken out from the pattern formed body manufacturing apparatus, and the photomask is left as it is in the pattern formed body manufacturing apparatus. Subsequently, another pattern forming substrate is patterned in the pattern formed body manufacturing apparatus under the same conditions as described above to produce a pattern formed body.

Thereafter, the same test as described above is performed plural times while the period when the photomask is left as it is, is changed. In each of the repeated tests, the property varied pattern of the firstly-formed pattern formed body is compared with that of the secondly-formed pattern formed body as follows. First, the property varied pattern of the firstly-formed pattern formed body is measured in various manners. The resultant values are used as reference values. Thereafter, the property varied pattern of the secondly-formed pattern formed body is measured in the same manners. It is decided whether or not the measured values of the property varied pattern of the secondly-formed pattern forming substrate are equal to the reference values. The kinds of properties to be measured are appropriately selected in accordance with the kind of the property to be varied of the property varied pattern, or the like. For example, the surface roughness of the above-mentioned pattern formed bodies may be measured with a surface roughness meter, or the shapes of the pattern formed bodies may be observed with an optical microscope, an X-ray photoelectron spectrometer, or the like. The contacts angles of the property varied patterns may be measured with a contact angle measuring device or the like. The contact angles can each be calculated from the value measured by use of, for example, a contact angle measuring device (CA-Z model, manufactured by Kyowa Interface Science Co., Ltd.) after a predetermined time from the dropping of a liquid droplet from a micro syringe. In such a way, a leaving period of the photomask when the measured values of the property varied pattern of the secondly-formed pattern formed body become equal to the reference values of the property varied pattern of the firstly-formed pattern formed body is estimated. Thus, a period when the photomask is to be left as it is in the above-mentioned foreign matter removing step is decided. The period when the photomask is to be left as it is in the foreign matter removing step is set to a period which is equal to or longer than the estimated period.

(2) Method of Using Gas to Remove the Foreign Matter from the Photomask

Next, the method of using gas to remove the foreign matter from the photomask is described herein. Specific examples of this method include a method of blowing an inert gas or the like onto the photomask to remove the foreign matter by the wind pressure thereof, a method of suctioning the foreign matter from the photomask surface to remove the foreign matter, and a method of releasing the foreign matter deposited to the photomask surface by wind pressure and suctioning the foreign matter. According to these methods, the foreign matter can be effectively removed without using any especial apparatus.

When the foreign matter is removed by wind pressure, the manner of blowing gas onto the photomask may be a manner of using an air-blowing nozzle or the like, which is ordinarily used to wash an apparatus. Examples of the inert gas blown onto the photomask include air, argon gas, and nitrogen gas. In the invention, the gas may be blown onto the whole of the surface of the photomask at a time, or may be blown continuously or intermittently onto individual portions of the photomask. The period when the gas is blown onto the photomask, the wind pressure, and so on are appropriately selected in accordance with the kind and amount of the foreign matter deposited to the photomask, or others.

The method of suctioning the foreign matter deposited to the photomask may be, for example, a method of putting the photomask into a vacuum device to suck the foreign matter, and is preferably a method of suctioning the foreign matter deposited to the photomask surface through an inspiratory nozzle in the invention. This makes it possible to remove the foreign matter effectively from the photomask and further produces an advantage that when a pattern formed body manufacturing apparatus in the item “B. Pattern formed body manufacturing apparatus” that will be described later is used, the removal of the foreign matter can be effectively attained without taking out the photomask from this pattern formed body manufacturing apparatus. The inspiratory nozzle may be, for example, the same nozzle as used in ordinary cleaners. The shape thereof may be a shape making it possible to absorb the foreign matter at a time from the whole of the surface of the photomask, or a shape making it possible to suck the foreign matter continuously or intermittently from individual portions of the photomask. The suctioning period, the suctioning pressure, and so on are appropriately selected in accordance with the kind of the foreign matter deposited to the photomask, and others.

The method of releasing the foreign matter deposited to the photomask surface by wind pressure and suctioning the foreign matter may be, for example, a method of using a combination of the above-mentioned nozzle for blowing gas with the above-mentioned inspiratory nozzle.

(3) Method of Using a Liquid to Remove the Foreign Matter from the Photomask

Next, the method of using a liquid to remove the foreign matter from the photomask is described herein. This method in the invention may be, for example, a method of washing the photomask with a liquid. Specific examples thereof include a method of immersing the photomask into a liquid and using a solubility of the foreign matter in the liquid, or the like to remove the foreign matter; a method of blowing a liquid onto the photomask with a nozzle or the like and using a solubility of the foreign matter in the liquid and the pressure of the liquid to remove the foreign matter; and a method of removing the foreign matter deposited to the photomask by action of water vapor. Of these methods, preferred in the invention are the method of blowing a liquid from a nozzle to remove the foreign matter, and the method of removing the foreign matter by action of water vapor. These methods make it possible to remove the foreign matter effectively. Moreover, these methods have an advantage that when a pattern formed body manufacturing apparatus in the item “B. Pattern formed body manufacturing apparatus”, which will be describe later, is used, the foreign matter can be effectively removed without taking out the photomask from this apparatus.

The nozzle used in the blowing of the liquid may be, for example, identical with a nozzle used in ordinary spray washing. The liquid used in the present method is preferably a liquid in which the foreign matter is highly dissolved. The kind of the liquid is appropriately selected in accordance with the kind of the foreign matter deposited to the photomask, and others. This solution may be selected from water and various organic solvents. The above-mentioned nozzle may be a nozzle capable of blowing the liquid onto the whole of the surface of the photomask at a time, or blowing the liquid continuously or intermittently onto individual portions of the photomask. The period when the liquid is blown, the blowing pressure of the liquid, and others are appropriately selected in accordance with the kind of the foreign matter deposited to the photomask, and other factors. In this case, the following step may be appropriately performed after the blowing of the liquid is performed: a step of wiping off the liquid from the photomask, a step of drying the photomask, or some other step.

Examples of the method of removing the foreign matter deposited to the photomask by action of water vapor include a method of leaving the photomask as it is in the atmosphere of water vapor, and a method of blowing water vapor onto the photomask. The temperature of the water vapor is appropriately selected in accordance with the kind of the foreign matter, and other factors. Under normal pressure, the temperature is usually from about 100 to 1000° C., preferably from about 100 to 500° C., more preferably from about 100 to 300° C. The manner for generating the water vapor may be the same manner as used in an ordinary water vapor generating device, such as a humidifier or a steam iron.

(4) Method of Contacting a Solid Material with the Photomask to Remove the Foreign Matter Therefrom

Next, the method of contacting a solid material with the photomask to remove the foreign matter therefrom is described herein. Examples of this method include a method of bringing an adsorbing plate having adsorptivity into contact with the photomask to adsorb and remove the foreign matter from the photomask, and a method of using a brush to wipe off the foreign matter from the photomask.

The adsorbing plate having adsorptivity may be, for example, a substrate or sheet having adhesiveness. When such an adsorbing plate is used, the adsorbing plate is brought into contact with the surface of the photomask and then the adsorbing plate is peeled from the photomask, whereby the foreign matter deposited to the photomask can be transferred onto the side of the adsorbing plate. The kind and properties of the adsorbing plate are not particularly limited as long as the plate is a plate which has adhesiveness to the foreign matter and can be peeled from the photomask. Thus, the adsorbing plate is appropriately selected in accordance with the kind of the foreign matter, and others, and may be, for example, a member in which an ordinary adhesive layer is formed on a substrate.

The above-mentioned brush is not particularly limited as long as the brush does not damage the photomask, and may be the same brush as used to wash ordinary devices.

(5) Method of Using Energy to Remove the Foreign Matter from the Photomask

Next, the method of using energy to remove the foreign matter from the photomask is described herein. Examples of this method include a method of radiating thermal energy to the photomask to volatilize or the like the foreign matter deposited to the photomask; a method of radiating ultrasonic energy to the photomask to remove the foreign matter from the photomask; a method of radiating plasma to the photomask; a method of radiating an electron beam to the photomask; a method of radiating positively- and/or negatively-charged ions to the photomask; a method of radiating vacuum-ultraviolet light to the photomask; and a method of using the action of a photocatalyst accompanying energy radiation to remove the foreign matter deposited to the photomask.

The method of using thermal energy maybe, for example, a method of heating the foreign matter deposited to the photomask to volatilize or the like the foreign matter from the photomask, specifically a method of heating the photomask up to a temperature which is higher than the boiling point of the foreign matter. The temperature is appropriately selected in accordance with the kind of the foreign matter and other factors, however, it maybe usually from about 20 to 300° C., preferably from about 50 to 200° C. The method for the heating is, for example, a method using a hot plate, an infrared heater or an oven. The heating period is appropriately selected in accordance with the kind and amount of the foreign matter, and others.

The method for radiating ultrasonic waves may be equivalent to an ordinary ultrasonic washing method, and is, for example, a method of immersing the photomask into a washing liquid keeping tank, in which a washing liquid is poured and kept, and then radiating ultrasonic waves to the photomask.

The method of radiating plasma to the photomask is not particularly limited as long as the method makes it possible to use plasma to remove the foreign matter deposited to the photomask surface. The method may be, for example, a method of radiating plasma in a vacuum, or a method of radiating plasma under an atmospheric pressure. Usually, the plasma is radiated onto the photomask surface side onto which the foreign matter is deposited.

In the invention, the above-mentioned plasma radiation is in particular preferably plasma radiation under an atmospheric pressure. This makes it possible to make any pressure-reducing device or the like unnecessary to produce good results from the viewpoint of costs or manufacturing efficiency. Conditions for this atmospheric pressure plasma radiation can be set as follows. For example, the power of the power supply may be the same as used in an ordinary atmospheric pressure plasma radiating device. At this time, the distance between the electrode for the radiated plasma and the photomask is set preferably into the range of about 0.2 to 20 mm, more preferably into the range of about 1 to 5 mm. The speed at which the substrate is transported is preferably from about 0.1 to 10 m/min., more preferably from about 0.5 to 5 m/min.

The method of radiating an electron beam to the photomask is not particularly limited as long as the method makes it possible to radiate an electron beam through which the foreign matter deposited to the photomask surface can be removed. The method for removing this electron beam may be specifically a method of using a known device, such as a device in which a uniform electron beam can be radiated in a curtain form from a linear filament (e.g., an electro-curtain type device), or an electron beam radiating device for the formation of photomasks. The electron beam radiating amount at this time is appropriately selected in accordance with the kind and the amount of the foreign matter. When an electron beam having acceleration energy of 1 to 30 Mrad is radiated to the surface of the photomask, the foreign matter on the surface is usually decomposed; thus, this radiating amount is preferred. If the electron beam amount is too low, expected effects cannot be obtained. On the other hand, if the electron beam amount is too high, the surface of the photomask may be damaged.

The method of radiating positively- or negatively-charged ions to the photomask is not particularly limited as long as the method makes it possible to radiate ions capable of removing the foreign matter deposited to the photomask surface. This radiating method may be, for example, a method of using an ordinary ion generating device (i.e., an ionizer), or the like. The radiated ions may be positively-charged ions, negatively-charged ions, or both of the ions.

The method of radiating vacuum-ultraviolet light to the photomask is not particularly limited as long as the method makes it possible to radiate vacuum-ultraviolet light by which the foreign matter deposited to the photomask surface can be removed. Usually, the wavelength of the vacuum-ultraviolet light used in this method is set preferably into the range of 100 to 250 nm, more preferably into the range of 150 to 200 nm. When the vacuum-ultraviolet light having a wavelength in this range is radiated, the foreign matter deposited to the photomask can be effectively removed.

Examples of a light source used in such radiation of vacuum-ultraviolet light include an excimer lamp, a low-pressure mercury lam, and other various lamps.

The direction in which the vacuum-ultraviolet light is radiated is not particularly limited as long as the direction is a direction making it possible to give the action of the vacuum-ultraviolet light to the area where the foreign matter deposits onto the photomask. For example, the vacuum-ultraviolet light may be radiated onto and through the photomask surface side onto which the foreign matter does not deposit. In the invention, it is particularly preferred to radiate the vacuum-ultraviolet light onto the photomask surface side on which the foreign matter is deposited. This makes it possible to remove also a foreign matter deposited onto a light shielding part, which is usually formed in the photomask. The radiation energy amount of the vacuum-ultraviolet light is rendered a radiation amount necessary for removing the foreign matter deposited to the photomask.

The method of using a photocatalyst accompanying energy radiation to remove the foreign matter deposited to the photomask may be, for example, a method of preparing a photocatalyst containing layer side substrate comprising a base material and a photocatalyst containing layer which is formed on the base material and at least comprises a photocatalyst, arranging the photomask and the photocatalyst containing layer side substrate so as to oppose the photomask surface onto which the foreign matter is deposited and the photocatalyst containing layer to each other, and then radiating energy to the photocatalyst containing layer, thereby removing the foreign matter deposited to the photomask surface.

The energy used in this method is not particularly limited as long as the energy makes it possible to excite the photocatalyst. Thus, the energy is not limited to any visible light. Usually, the wavelength of the energy used is set to be in the range of 400 nm or less, preferably 150 nm to 380 nm. This is because, as described later, a preferred example of the photocatalyst used in the photocatalyst containing layer is titanium dioxide; the energy for activating the photocatalyst action by the titanium dioxide is preferably the energy of the above-mentioned wavelength.

Examples of a light source that can be used in the energy radiation include a mercury lamp, a metal halide lamp, a xenon lamp, an excimer lamp, and various other light sources. Further, it is possible to use a method of using a laser such as an excimer laser or a YAG laser.

The direction in which the energy is radiated is not particularly limited as long as the direction is a direction making it possible to give the action of the photocatalyst to the area of the photomask onto which the foreign matter is deposited. For example, when the photomask is arranged to be opposed to the photocatalyst containing layer of the photocatalyst containing layer side substrate, the energy may be radiated onto the side of the photomask. In the invention, it is particularly preferred to radiate the energy onto the side of the photocatalyst containing layer side substrate. This makes it possible to give the action of the photocatalyst effectively onto the whole of the surface of the photomask.

At the time of the energy radiation, the radiation amount of the energy is set to a radiation amount necessary for removing the foreign matter deposited to the photomask surface. At this time, the sensitivity of the photocatalyst can be made high by radiating the energy while heating the photocatalyst containing layer. Thus, the foreign matter can be effectively decomposed and removed from the photomask. From this viewpoint, this manner is preferable. Specifically, it is preferred to heat the layer at a temperature from 30 to 80° C.

The photocatalyst containing layer, which is used in the photocatalyst containing layer side substrate, is not particularly limited as long as the photocatalyst in this layer makes it possible to remove the foreign matter deposited to the photomask arranged to be opposed to the layer. The photocatalyst containing layer may be a layer composed of the photocatalyst and a binder, or a film made only of the photocatalyst. The property of the surface thereof may be lyophilic or liquid repellent.

As the photocatalyst used in the present invention, those known as semiconductors, such as titanium dioxide (TiO₂), zinc oxide (ZnO), tin oxide (SnO₂), strontium titanate (SrTiO₃), tungsten oxide (WO₃), bismuth oxide (Bi₂O₃), and iron oxide (Fe₂O₃) can be presented. Apart from the semiconductors, metal complex and silver can be presented as examples. One or at least two kinds as a mixture can be selected and used from them in the present invention.

According to the present invention, in particular, a titanium dioxide can be used preferably since it has high band gap energy, it is chemically stable without the toxicity, and it can be obtained easily. There are an anatase type and a rutile type in the titanium dioxides, and either can be used in the present aspect, however, the anatase type titanium dioxide is preferable. The anatase type titanium dioxide has a 380 nm or less excitation wavelength.

As the anatase type titanium dioxide, for example, a hydrochloric acid deflocculation type anatase type titania sol (STS-02 (average particle diameter 7 nm) manufactured by ISHIHARA SANGYO KAISHA, LTD., ST-K01 manufactured by ISHIHARA SANGYO KAISHA, LTD.), or a nitric acid deflocculation type anatase type titania sol (TA-15 (average particle diameter 12 nm) manufactured by Nissan Chemical Industries, Ltd.) can be presented.

As the titanium oxide, visible ray responsible titanium oxide may be used. The visible ray responsible titanium oxide is excited also by visible ray energy. As an example of the method for making titanium oxide into such a visible ray responsible type may be a method of subjecting titanium oxide to nitriding treatment.

The nitriding treatment of titanium oxide referred to the invention is, for example, a treatment of substituting some parts of oxygen sites in titanium oxide (TiO₂) crystal with nitrogen atoms; a treatment of doping spaces between crystal lattices of titanium oxide (TiO₂) with nitrogen atoms; or a treatment of arranging nitrogen atoms in grain boundaries of polycrystalline aggregates of titanium oxide (TiO₂) crystal.

The method for the nitriding treatment of titanium oxide (TiO₂) is not particularly limited, and is, for example, a method of subjecting fine particles of crystalline titanium oxide to thermal treatment at 700° C. in an ammonia atmosphere to dope the particles with nitrogen, and then using an inorganic binder, a solvent or the like to make the nitrogen-doped fine particles into a liquid dispersion.

With a smaller particle diameter of the photocatalyst in the photocatalyst containing layer, the photocatalytic reaction can be generated more effectively, and thus it is preferable. An average particle diameter of 50 nm or less is preferable, and use of a photocatalyst of 20 nm or less is particularly preferable.

The photocatalyst containing layer in the invention may be a layer made only of the photocatalyst, or a layer formed by mixing the photocatalyst with a binder, as described above. The method for forming the photocatalyst containing layer made only of the photocatalyst may be a method as described in, e.g., JP-A No. 2000-249821.

In the case of using a binder, the binder is preferably a binder having a principal skeleton having such a high bonding energy that the principal skeleton is not decomposed by optical excitation of the photocatalyst. An example thereof is an organopolysiloxane. Further, an amorphous silica precursor can be presented as the binder. The organopolysiloxane and the amorphous silica precursor may be those described in, e.g., JP-A No. 2000-249821.

In the photocatalyst containing layer, a surfactant, an additive and the like can be used besides the photocatalyst and the binder. For example, substances as disclosed in JP-A No. 2000-249821 can be used.

The base material used in the photocatalyst containing layer side substrate is not particularly limited as long as the base material is a material on which the photocatalyst containing layer can be formed. The base material may be, for example, a flexible resin film, or a non-flexible member such as a glass substrate.

An intermediate layer may be formed on the base material in order to improve the adhesive property between the base material surface and the photocatalyst contaning layer, or prevent the base material from being deteriorated by the action of the photocatalyst. An example of this intermediate layer is a film made of a silane or titanium based coupling agent, or a silica film formed by such as reactive sputtering or CVD.

(Photomask)

Next, the photomask, from which the foreign matter is removed in the present step, is described herein. This photomask is not particularly limited as long as the photomask is a photomask which is used when vacuum-ultraviolet light is radiated to the pattern forming substrate and makes it possible to radiate the vacuum-ultraviolet light to the area where the above-mentioned property varied pattern is to be formed. As illustrated in, e.g., FIG. 1A, this photomask usually has a transparent base material 5 and a light shielding part 6 formed on the transparent base material 5.

Each of the constituents of the photomask will be described hereinafter.

a. Light Shielding Part

First, the light shielding part used in the photomask is described herein. This light shielding part is not particularly limited as long as the part is a part which is formed on the transparent base material, which will be detailed later, contributes to the formation of the property varied pattern, and does not transmit vacuum-ultraviolet light. The material of this light shielding part is appropriately selected in accordance with properties of the face where the light shielding part is to be formed, the method for forming the light shielding part, and others.

For example, the light shielding part may be formed by forming a thin film, about 300 to 2000 Å in thickness, made of a metal such as chromium by sputtering, vacuum vapor deposition or the like, and then patterning this thin film. The method for the patterning may be, for example, an ordinary patterning method such as sputtering, metal etching, or lifting-off.

The method for forming this light shielding part may be, for example, a method of forming a layer wherein light shielding particles made of such as carbon fine particles, a metal oxide, an inorganic pigment, or an organic pigment are incorporated into a resin binder into a pattern form. Examples of the resin binder to be used may be: a single or mixture made of one or more selected from resins such as polyimide resin, acrylic resin, epoxy resin, polyacrylamide, polyvinyl alcohol, gelatin, casein and cellulose; a photosensitive resin; or an O/W emulsion type resin composition such as a product obtained by emulsifying reactive silicone. The method for patterning this resin light shielding part may be an ordinarily-used method, such as photolithography or printing.

About the position where the light shielding part is formed is as follows: the light shielding part may be formed on the transparent base material side which is to face the pattern forming substrate when the photomask and the pattern forming substrate are arranged to oppose to each other, or may be formed on the transparent base material side which is not to face the pattern forming substrate at that time.

The shape of the light shielding part is not particularly limited, and can be appropriately selected in accordance with the pattern to be formed in the pattern forming substrate, and others.

The width of lines of the light shielding part is set usually to a value of about 0.1 μm or more, preferably to a value of about 1 μm or more. When the width is set into this range, the property varied pattern can be formed into a target pattern form without being affected by diffraction of the vacuum-ultraviolet light.

b. Transparent Base Material

Next, the transparent base material used in the photomask is described herein. This transparent base material is not particularly limited as long as the transparent base material is a base material which has transmittance to vacuum-ultraviolet light and on which the light shielding part can be formed. The transparent base material may be a transparent base material used in an ordinary photomask. Specific examples of this transparent base material include transparent rigid materials, which are not flexible, such as a quartz plate, a Pyrex (registered trademark) glass, and a synthetic quartz plate; and transparent flexible materials, such as a transparent resin film, or an optical resin plate. If necessary, the base material may be subjected to surface treatment to prevent elution-out of alkalis, give gas barrier performance, and attain other purposes.

In order to improve adhesion between the surface of the transparent base material and the light shielding part, an anchor layer may be formed on the transparent base material. This anchor layer may be made of, for example, a silane-, or titanium-coupling agent.

2. Patterning Forming Step

Next, the pattern forming step in the invention is described herein. This step is a step of radiating the vacuum-ultraviolet light through a photomask to a pattern forming substrate having a surface the property of which is varied by action of the vacuum-ultraviolet light, thereby forming, on the surface of the pattern forming substrate, a property varied pattern, in which the property is varied, so as to form a pattern formed body. In the invention, the pattern forming step is performed at least two times. The number of repeated times of the step is not particularly limited.

In the invention, the above-mentioned foreign matter removing step is performed between the plural pattern-forming steps; therefore, it is possible to prevent the foreign matter deposited to the photomask used in the pattern forming steps from contributing to the formation of any one of the property varied patterns. Thus, it becomes possible to manufacture pattern formed bodies in which target property varied patterns are formed with a high precision.

The pattern forming substrate used in the present step, and the method for radiating vacuum-ultraviolet light will each be described hereinafter.

(Pattern Forming Substrate)

First, the pattern forming substrate used in the invention is described herein. The pattern forming substrate is not particularly limited about its structure as long as the pattern forming substrate is a substrate the surface property of which is variable by action of vacuum-ultraviolet light when the vacuum-ultraviolet light is radiated through the photomask.

The pattern forming substrate may be, for example, a member having a supporting substrate and a property variable layer the surface property of which is varied by action of vacuum-ultraviolet light, or a member made only of a property variable layer the surface property of which is varied by action of vacuum-ultraviolet light. In the invention, it is particularly preferred that the property variable layer is a layer containing an organic material. In the case where the property variable layer contains an organic material, a foreign matter deposits onto the photomask with particular ease when the vacuum-ultraviolet light is radiated through the photomask to the pattern forming substrate; thus, it is possible to make the best use of the advantage of the invention.

The kind of the variable property of the property variable layer in the pattern forming substrate is not particularly limited, and may be, for example, surface wettability variable by action of vacuum-ultraviolet light, adhesiveness to a specified substance variable by action of vacuum-ultraviolet light. In the invention, the property variable layer is preferably a layer the surface wettability of which is varied by action of vacuum-ultraviolet light, more preferably a wettability variable layer the contact angle of which with a liquid is lowered by action of vacuum-ultraviolet light. This makes it possible to render the area where the wettability is varied in the present step a lyophilic area and render the area where the wettability is not varied in the present step a liquid repellent area. Accordingly, when a functional part forming coating solution is coated onto a pattern formed body manufactured by the invention by, for example, a coating method, the functional part forming coating solution can be caused to adhere only to its property varied pattern, which is a lyophilic area. Consequently, a functional part can be made into a highly precise pattern form.

The lyophilic area is defined herein as an area having a lower contact angle with a liquid than that of any area adjacent thereto by 1° or more, and means an area which has a small contact angle with a liquid and has a good wettability to a functional part forming coating solution for forming a functional part. The liquid repellent area means an area which has a large contact angle with a liquid and has a bad wettability to the functional part forming coating solution.

The wettability variable layer used in the pattern forming substrate preferably has a contact angle of 10° or more with the liquid having a surface tension of 40 mN/m, and more preferably has a contact angle of 10° or more with the liquid having a surface tension of 20 mN/m in the state that the wettability of the layer is not varied for the following reason: the area where the wettability is not varied is an area required to have liquid repellency, and thus if the contact angle of the area with a liquid is small, the liquid repellency thereof is insufficient; therefore, for example, when the functional part forming coating solution is coated onto the pattern forming substrate, this coating solution may unfavorably remain on the liquid repellent area also.

When the action of vacuum-ultraviolet light is given to the wettability variable layer in the present step, the area where the wettability is varied preferably has a contact angle of 9° or less with the liquid having a surface tension of 40 mN/m, and more preferably has a contact angle of 10° or less with the liquid having a surface tension of 60 mN/m for the following reason: in the case where the contact angle of the area where the wettability is varied (that is, the lyophilic area) with a liquid is high, for example, at the time of coating the above-mentioned functional part forming coating solution, the lyophilic area may also repel this coating solution; thus, a functional part may not be easily formed on the lyophilic area.

The contact angle with respect to a liquid here is obtained from the results or a graph of the results of measuring (30 seconds after of dropping liquid droplets from a micro syringe) the contact angle with respect to liquids having various surface tensions using a contact angle measuring device (CA-Z type manufactured by Kyowa Interface Science, Co., Ltd). Moreover, at the time of the measurement, as the liquids having the various surface tensions, wetting index standard solution manufactured by JUNSEI CHEMICAL CO., LTD. were used.

This wettability variable layer, in which the wettability is varied by action of vacuum-ultraviolet light, may be, for example, a layer containing an organopolysiloxane, specifically a layer containing an organopolysiloxane as described in JP-A No. 2001-074928.

A surfactant, an additive and so forth may be used besides the organopolysiloxane. These may also be, for example, those as described in JP-A No. 2001-074928.

The film thickness of the property variable layer is appropriately selected in accordance with the kind of this layer or kind or usage of the pattern forming substrate, and is usually from about 0.01 μm to 1 mm, in particular, from about 0.1 μm to 0.1 mm.

When the pattern forming substrate has a supporting substrate, the supporting substrate is not particularly limited as long as the substrate can support the property variable layer, in which the property is varied. The kind, the flexibility, the transparency and other properties thereof are appropriately selected in accordance with the usage of the pattern formed body, and so on. In the invention, the supporting substrate may be made of an organic material or an inorganic material. Specifically, the substrate may be a resin film, or a glass, ceramic or metal, and is preferably a plate-form member.

(Radiation of Vacuum-Ultraviolet Light)

Next, the radiation of vacuum-ultraviolet light in the present step is described herein. In the present step, vacuum-ultraviolet light is radiated in a pattern form, along a predetermined direction, through the photomask to the pattern forming substrate.

The wavelength of the vacuum-ultraviolet light is set usually into the range of 100 to 250 nm, preferably into the range of 150 to 200 nm. This makes it possible to form a property varied pattern effectively in the pattern forming substrate.

A light source which can be used to radiate the vacuum-ultraviolet light may be selected from an excimer lamp, a low-pressure mercury lamp, and other various light sources.

The radiation energy amount of the vacuum-ultraviolet light when the vacuum-ultraviolet light is radiated is made into a radiation energy amount necessary for forming a property varied pattern, in which the property of the pattern forming substrate is varied. The shape, the area and other properties of the property varied pattern formed in the present step are appropriately selected in accordance with the kind, the usage and other properties of the pattern formed body.

When the vacuum-ultraviolet light is radiated, the photomask and the pattern forming substrate may be arranged in any form as long as they are arranged in the state that the action of the vacuum-ultraviolet light is given to the pattern forming substrate. The photomask and the pattern forming substrate may be arranged to adhere closely to each other. In the invention, it is preferred to arrange the photomask and the pattern forming substrate to make a gap therebetween. When the line width of the property varied pattern is set into the range of 1 to 100 μm, the width of this gap is set preferably into the range of 0.1 to 100 μm, more preferably into the range of 1 to 50 μm. When the light width of the property varied pattern is set into the range of more than 100 μm and 1000 μm or less, the gap is set preferably into the range of 10 to 200 μm, more preferably into the range of 50 to 200 μm. This makes it possible to pattern the pattern forming substrate evenly.

In the invention, it is sufficient that such an arrangement state of the photomask is maintained only during the radiation of the vacuum-ultraviolet light.

3. Others

The manufacturing method of a plurality of pattern formed bodies according to the invention is not particularly limited as long as the method comprises the foreign matter removing step and the pattern forming step. Thus, the method may have, for example, a step of producing the pattern forming substrate besides these steps.

Any one of the pattern formed bodies manufactured by the invention can be used to form, for example, a color filter in which a colored layer is formed on the above-mentioned property varied pattern, an organic EL element in which an organic EL layer is formed on the property varied pattern, or a microlens in which lenses are formed on the property varied pattern. According to the invention, the property varied pattern can be rendered a target pattern formed with a high precision; thus, various functional parts such as a colored layer and an organic EL layer can be formed with a high precision. Any one of the pattern formed bodies manufactured by the invention may be used as a cell culturing substrate in order to culture cells. In this case, cells can be cultured into a target pattern form on the property varied pattern with a high precision.

B. Pattern Formed Body Manufacturing Apparatus

Next, the pattern formed body manufacturing apparatus of the present invention will be explained. The pattern formed body manufacturing apparatus of the invention used at the time of manufacturing a plurality of pattern formed bodies, wherein the pattern formed bodies are manufactured by repeating plural times a pattern forming step which is a step of radiating vacuum-ultraviolet light through a photomask to a pattern forming substrate, varying a surface property by the vacuum-ultraviolet light, and forming a property varied pattern with the property varied on a surface of the pattern forming substrate to form a pattern formed body; and the apparatus comprises: a pattern forming substrate supporting section for supporting the pattern forming substrate, a photomask supporting section for supporting the photomask to be oppose to the pattern forming substrate, a vacuum-ultraviolet light radiating section for radiating the vacuum-ultraviolet light to the pattern forming substrate, and foreign matter removing means for removing a foreign matter deposited to the photomask.

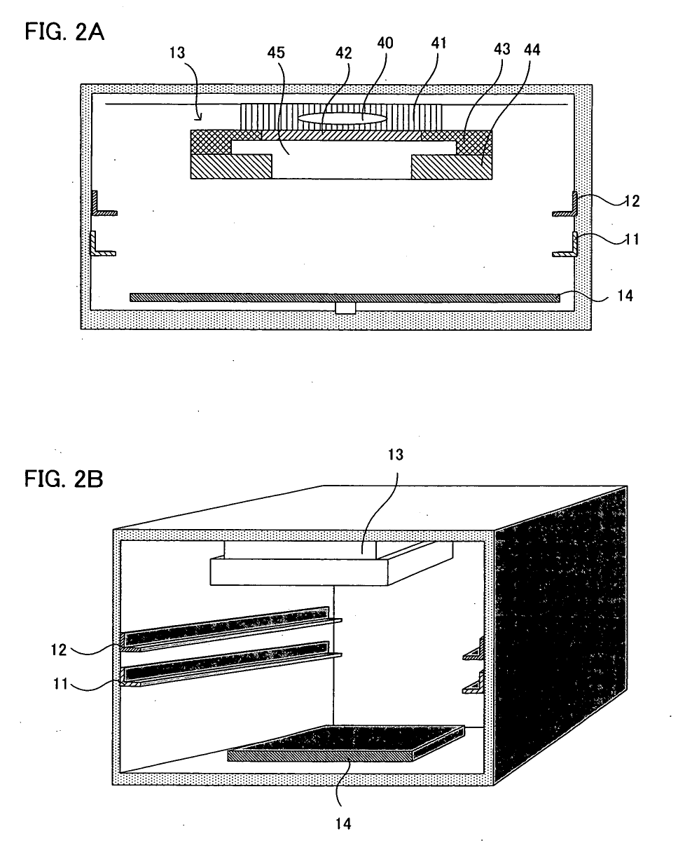

As illustrated in, for example, FIG. 2A as a sectional view, and FIG. 2B as a perspective view, the pattern formed body manufacturing apparatus of the invention has a pattern forming substrate supporting section 11 for supporting a pattern forming substrate, a photomask supporting section 12 for supporting a photomask, a vacuum-ultraviolet light radiating section 13 for radiating vacuum-ultraviolet light to the pattern forming substrate, and foreign matter removing means 14 for removing a foreign matter deposited to the photomask.

In the pattern formed body manufacturing apparatus of the invention, a pattern forming substrate is caused to be supported on the pattern forming substrate supporting section, a photomask is caused to be supported on the photomask supporting section, and then vacuum-ultraviolet light is radiated from the vacuum-ultraviolet light radiating section. In this way, a property varied pattern, in which the property of the pattern forming substrate is varied, is formed in the pattern forming substrate to manufacture a pattern formed body. In this manufacturing method of the pattern formed body, the apparatus is used.

As described above, in the case of radiating, in the prior art, vacuum-ultraviolet light through the photomask to a pattern forming substrate, thereby patterning the pattern forming substrate, a decomposition product or the like that is generated on the pattern forming substrate may vaporize so as to adhere to the photomask, which is arranged to be opposed to the pattern forming substrate. Thus, when other pattern forming substrates are continuously patterned, any foreign matter deposits to this photomask may contribute to a change in the property of each of the other pattern forming substrates, or the foreign matter may hinder the action of oxygen atom radicals generated by action of the vacuum-ultraviolet light. Accordingly, when plural pattern formed bodies are continuously manufactured, there arises a problem that it is difficult to make property varied patterns formed on the pattern formed bodies into a target form, that is, to make lines of these property varied patterns uniform (i.e., equal to each other).

In the invention, however, the pattern formed body manufacturing apparatus has the foreign matter removing means; therefore, any foreign matter can be removed between the plural pattern-forming steps. Accordingly, even if the photomask is used to vary the property of the pattern forming substrates in a pattern form so as to manufacture pattern formed bodies continuously, the use of the pattern formed body manufacturing apparatus of the invention causes any foreign matter deposited to the photomask not to produce an effect onto the formation of the property varied patterns. Consequently, pattern formed bodies in which a target property varied pattern is formed with a high precision can be manufactured.

Each of the constituents of the pattern formed body manufacturing apparatus of the invention will be described in detail hereinafter.

1. Foreign Matter Removing Means

First, the foreign matter removing means used in the invention is described herein. This means is not particularly limited as long as the means is means capable of removing a foreign matter deposited to a photomask used to manufacture pattern formed bodies. The means may be moved in three-dimensional directions, or may be fixed in the pattern formed body manufacturing apparatus. As illustrated in FIGS. 2A and 2B, the means may be means for removing the foreign matter in the state that the photomask supporting section 12 supports a photomask, or may be, for example, means for removing the foreign matter deposited to the photomask in the state that the photomask is taken off from the photomask supporting section.

Examples of this foreign matter removing means include means for using gas to remove the foreign matter from the photomask, means for using a liquid to remove the foreign matter from the photomask, means for using a solid material to remove the foreign matter from the photomask, and means for using energy to remove the foreign matter from the photomask. These foreign matter removing means may be formed alone or in combination of at least two thereof.

Each of these means will be described in detail hereinafter.

(1) Means for Using Gas to Remove the Foreign Matter from the Photomask

Herein, the means for using gas to remove the foreign matter from the photomask is described. Specific examples of this means include gas blowing means for removing the foreign matter by wind pressure, suctioning means for suctioning the foreign matter from the surface of the photomask to remove the foreign matter, and means made of a combination of the gas blowing means and the suctioning means.

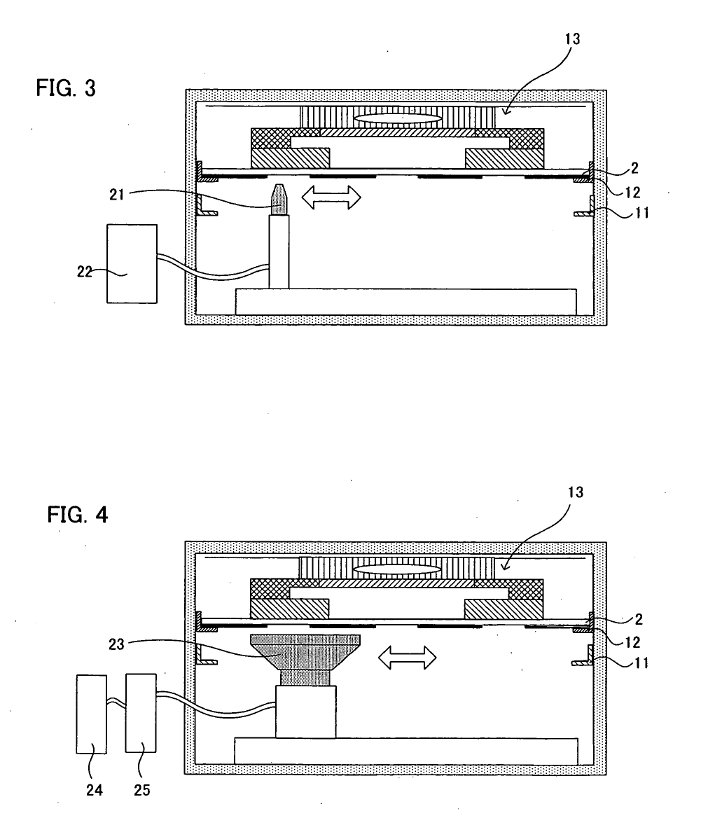

As illustrated in, for example, FIG. 3, the gas blowing means may be means having a blowing nozzle section 21 for blowing gas onto a photomask 2 supported on a photomask supporting section 12, and a gas supplying section 22 for supplying the gas to the blowing nozzle section 21. The blowing nozzle section may have a shape capable of blowing the gas onto the whole of the surface of the photomask, or a shape capable of blowing the gas onto the photomask partially. This blowing nozzle section may be identical with an air-blowing nozzle used for ordinary washing. Usually, this blowing nozzle has a shifting mechanism for shifting the nozzle to the vicinity of the photomask supported on the photomask supporting section after the pattern forming substrate is taken off from the pattern forming substrate supporting section, which will be detailed later. The blowing nozzle may have a shifting mechanism for shifting the nozzle in two-dimensional directions along the surface of the photomask.

The gas supplying section is not particularly limited as long as the section can supply gas to the nozzle section, and may be identical with an ordinary compressor or the like. The kind and other properties of the gas blown to the photomask may be the same described in the above-mentioned item “A. Manufacturing method of a plurality of pattern formed bodies”.

As illustrated in, for example, FIG. 4, the suctioning means for suctioning the foreign matter from the surface of the photomask to remove the foreign matter may be means having a gas-inspiratory nozzle section 23 for suctioning the foreign matter from the surface of the photomask 2 supported on a photomask supporting section 12, a gas-inspiratory section 24 for suctioning gas, a storing section 25 for storing the foreign matter suctioned by the gas-inspiratory nozzle section, and so on.

The gas-inspiratory nozzle section may have a shape capable of suctioning the foreign matter from the whole of the surface of the photomask at a time, or a shape capable of suctinoning the foreign matter from the photomask partially. This gas-inspiratory nozzle section may have the same structure as a nozzle used in an ordinary cleaner. Usually, this gas-inspiratory nozzle has a shifting mechanism for shifting the nozzle to the vicinity of the photomask supported on the photomask supporting section after the pattern forming substrate is taken off from the pattern forming substrate supporting section, which will be detailed later. The gas-inspiratory nozzle may have a shifting mechanism for shifting the nozzle in two-dimensional directions along the surface of the photomask.

The storing section is not particularly limited as long as the section is arranged between the gas-inspiratory nozzle section and the gas-inspiratory section and is capable of storing the foreign matter suctioned from the gas-inspiratory nozzle section. If the gas-inspiratory nozzle section and the gas-inspiratory section are directly connected to each other, the gas-inspiratory section is blocked by the foreign matter suctioned from the gas-inspiratory nozzle section; consequently, a breakdown is caused. This storing section may have the same structure as a storing section fitted to an ordinary cleaner.

The gas-inspiratory section is not particularly limited as long as the section is capable of suctioning gas through a predetermined pressure, and may be the same gas-inspiratory section as fitted to an ordinary cleaner.

The means made of a combination of the gas blowing means and the suctioning means may be means having a blowing nozzle section for blowing gas to the photomask, a gas-inspiratory nozzle section for suctioning the foreign matter released from the photomask by the gas, a storing section for storing the foreign matter suctioned from the gas-inspiratory nozzle section, a gas circulating section for supplying the gas suctioned from the gas-inspiratory nozzle section to the blowing nozzle section, and so on. The blowing nozzle section, the gas-inspiratory nozzle section, and the storing section may be the same as described above. The gas circulating section may be the same gas circulating section as used in an ordinary machine.

(2) Means for Using a Liquid to Remove the Foreign Matter from the Photomask

Next, the means for using a liquid to remove the foreign matter from the photomask is described herein. Specific examples of this means in the invention include immersing means for immersing the photomask into a liquid and removing the foreign matter by use of solubility of the foreign matter in the liquid, means for blowing a liquid to the photomask through a nozzle or the like to wash the photomask, and means for removing the foreign matter deposited to the photomask by action of water vapor.

The immersing means may be, for example, means having a solution keeping section capable of keeping a solution in which the foreign matter can be dissolved. The solution keeping section is not particularly limited as long as the section is a section which keeps a solution in which the foreign matter can be dissolved and which the photomask can be immersed in. The kind and other properties of the solution kept in the solution keeping section are appropriately selected in accordance with the kind, the amount and other properties of the foreign matter.

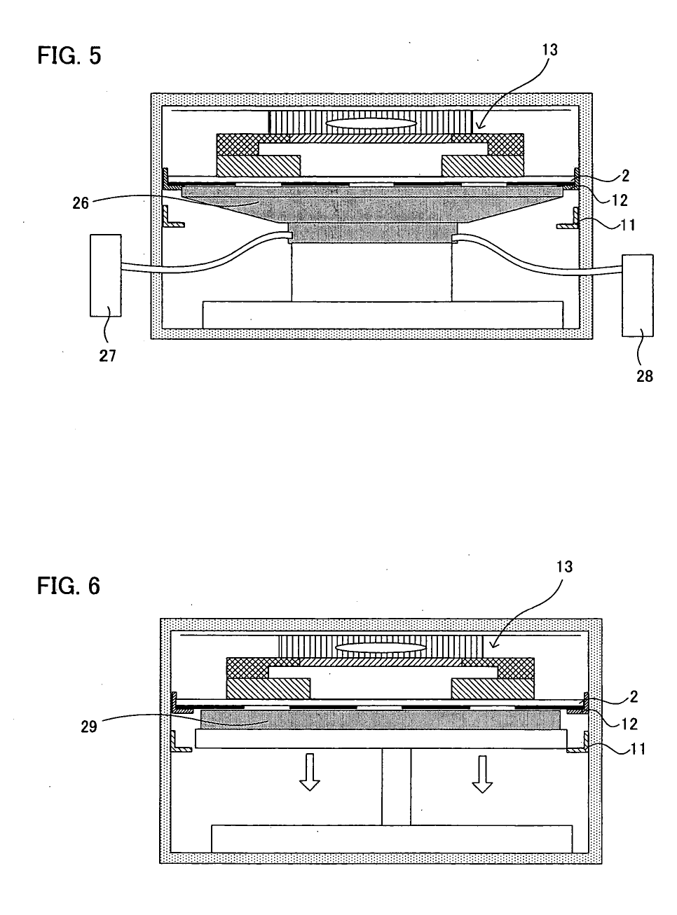

As illustrated in, for example, FIG. 5, the washing means may be means having a washing section 26 for jetting out a liquid to wash the surface of a photomask 2, a liquid supplying section 27 for supplying the liquid to the washing section 26, a suction drying section 27 for drying the photomask 2, and so on. The washing section is not particularly limited as long as the section is capable of jetting out a liquid onto the surface of the photomask to wash the photomask. The section may be, for example, a section capable of jetting out a liquid onto the whole of the surface of the photomask, or a section capable of jetting out a liquid onto the photomask partially. This washing section may have the same structure as a washing section which has a nozzle and so on and is used in an ordinary spray washing device. This washing section usually has a shifting mechanism for shifting the section to the vicinity of the photomask supported on the photomask supporting section after the pattern forming substrate is taken off from the pattern forming substrate supporting section, which will be detailed later. The washing section may have a shifting mechanism for shifting the section in two-dimensional directions along the surface of the photomask.

The solution supplying section is not particularly limited as long as the section makes it possible to supply a predetermined amount of a solution into the solution jetting section, and may have the structure as solution supplying means fitted to an ordinary spray washing device. The suction drying section is not particularly limited as long as the section makes it possible to dry the photomask, and may have the same structure as a suction drying section used in an ordinary washing device.

The washing means may have a temperature controlling section for drying the photomask thermally, a pressure controlling section for adjusting the pressure of the solution jetted out from the washing section, and some other section. The solution jetted out from the washing means may be the same as described in the above-mentioned item “A. Manufacturing method of a plurality of pattern formed bodies”.

The water vapor acting means may be, for example, means having a heating section for heating water to turn the water into water vapor, a water supplying section for supplying water to the heating section, and a jetting nozzle section for jetting out the water vapor. This heating section is not particularly limited as long as the section makes it possible to heat water to turn the water into water vapor, and may be, for example, the same as used in an ordinary humidifier, steam iron or the like. The water supplying section is not particularly limited as long as the section makes it possible to supply a predetermined amount of water to the heating section, and may be the same structure as water supplying means fitted to an ordinary humidifier or the like.

The jetting nozzle section may have a shape making it possible to jet out water vapor to the whole of the surface of the photomask, or a shape making it possible to jet out water vapor to the photomask partially. This jetting nozzle section may be identical with a water vapor jetting nozzle used in an ordinary humidifier. Usually, this jetting nozzle section has a shifting mechanism for shifting the section to the vicinity of the photomask supported on the photomask supporting section after the pattern forming substrate is taken off from the pattern forming substrate supporting section, which will be detailed later. The jetting nozzle section may have a shifting mechanism for shifting the section in two-dimensional directions along the surface of the photomask.

(3) Means of Contacting a Solid Material with the Photomask to Remove the Foreign Matter from the Photomask

Next, the means of contacting a solid material with the photomask to remove the foreign matter therefrom is described herein. Examples of this means include means of contacting an adsorbing plate having adsorptivity with the photomask to remove the foreign matter from the photomask, and means of using a brush to wipe off the foreign matter from the photomask.

As illustrated in, for example, FIG. 6, the adsorbing means is means having an adsorbing plate 29 having adsorptivity, and this adsorbing plate 29 has a shifting mechanism for peeling the plate from a photomask 2 after the plate 29 is caused to adhere closely to the photomask 2. The kind and other properties of the adsorbing plate are not particularly limited as long as the plate has adhesive property onto the foreign matter and can be peeled from the photomask. The adsorbing plate may be, for example, a member in which an ordinary adhesive layer is formed on a substrate, and is appropriately selected in accordance with the kind of the foreign matter, and others.

The above-mentioned means for using a brush is means having a brush section for washing the surface of the photomask, and this brush section has a mechanism for shifting the brush along the photomask after this section contacts the photomask. This brush section is not particularly limited as long as the section does not damage the photomask, and may be the same as used to wash an ordinary apparatus.

(4) Means for Using Energy to Remove the Foreign Matter from the Photomask

Next, the means for using energy to remove the foreign matter from the photomask is described herein. Examples of this means include thermal energy radiating means for radiating thermal energy to the photomask to volatilize the foreign matter deposited to the photomask, thereby removing the foreign matter; ultrasonic wave radiating means for radiating ultrasonic waves to the photomask to remove the foreign matter deposited to the photomask by vibration; vacuum-ultraviolet light radiating means for radiating vacuum-ultraviolet light; plasma radiating means for radiating plasma; electron beam radiating means for radiating an electron beam; ion radiating means for radiating positively- and/or negatively-charged ions; and photocatalyst acting means for using the action of a photocatalyst accompanying energy radiation to remove the foreign matter deposited to the photomask.

The thermal energy radiating means may be, for example, means having a heating section for raising the temperature of the inside of the pattern formed body manufacturing apparatus, and a temperature adjusting section for adjusting the temperature of the inside of the pattern formed body manufacturing apparatus. The heating section and the temperature adjusting section may be the same as used in, for example, an ordinary hot plate, heater, or oven. This energy radiating means may have a shifting mechanism for shifting the means to the vicinity of the photomask supported on the photomask supporting section after the pattern forming substrate is taken off from the pattern forming substrate supporting section, which will be detailed later.

The ultrasonic wave radiating means may be, for example, means having a washing solution keeping tank in which the photomask is immersed, and an ultrasonic wave radiating section for radiating ultrasonic waves to the photomask. The washing solution keeping tank is not particularly limited as long as the tank is a tank which can keep a washing solution capable of washing the photomask and which the photomask can be immersed in, and may be the same as used in an ordinary ultrasonic washer. The ultrasonic wave radiating section is not particularly limited as long as the section can radiate ultrasonic waves capable of removing the foreign matter from the surface of the photomask, and may be the same as used an ordinary ultrasonic washer.

The vacuum-ultraviolet light radiating means is not particularly limited as long as the means is capable of radiating vacuum-ultraviolet light to the photomask to remove the foreign matter, and may be, for example, means having a light source from which vacuum-ultraviolet light can be radiated. This light source may be selected from an excimer lamp, a low-pressure mercury lamp, and other various light sources. The method for radiating vacuum-ultraviolet light by use of this vacuum-ultraviolet light radiating means may be the same as described in the sub-item “Foreign matter removing step” in the item “A. Manufacturing method of a plurality of pattern formed bodies”. Thus, the description thereof is omitted herein.

The plasma radiating means is not particularly limited as long as the means is capable of radiating plasma to the photomask to remove the foreign matter, and may be, for example, means for radiating plasma in a vacuum, or means for radiating plasma under an atmospheric pressure. In the invention, the latter means is particularly preferred since the machine therefor can easily be designed. This plasma radiating means may be the same as in an ordinary plasma radiating apparatus. The method for radiating plasma by use of this plasma radiating means may be the same as described in the sub-item “Foreign matter removing step” in the item “A. Manufacturing method of a plurality of pattern formed bodies”. Thus, the description thereof is omitted herein.

The means for radiating an electron beam to the photomask is not particularly limited as long as the means is capable of radiating an electron beam making it possible to decompose and remove the foreign matter deposited to the photomask. This electron beam radiating means may be specifically the same as in an ordinary electron beam radiating apparatus. The method for radiating an electron beam by use of this electron beam radiating means may be the same as described in the sub-item “Foreign matter removing step” in the item “A. Manufacturing method of a plurality of pattern formed bodies”. Thus, the description thereof is omitted herein.

The ion radiating means for radiating positively- and/or negatively-charged ions may be, for example, means having an ion generating section for generating the ions, and a jetting nozzle section for jetting out the generated ions. This ion generating section may have the same structure as ion generating means in an ordinary ion generator (i.e., ionizer). The jetting nozzle section may have a shape capable of jetting out the ions onto the whole of the surface of the photomask, or a shape capable of jetting out the ions onto the photomask partially. This jetting nozzle section may be the same as used in an ordinary ionizer. This jetting nozzle section may have a shifting mechanism for shifting the section to the vicinity of the photomask supported on the photomask supporting section after the pattern forming substrate is taken off from the pattern forming substrate supporting section, which will be detailed later. The jetting nozzle section may have a shifting mechanism for shifting the section in two-dimensional directions along the surface of the photomask.

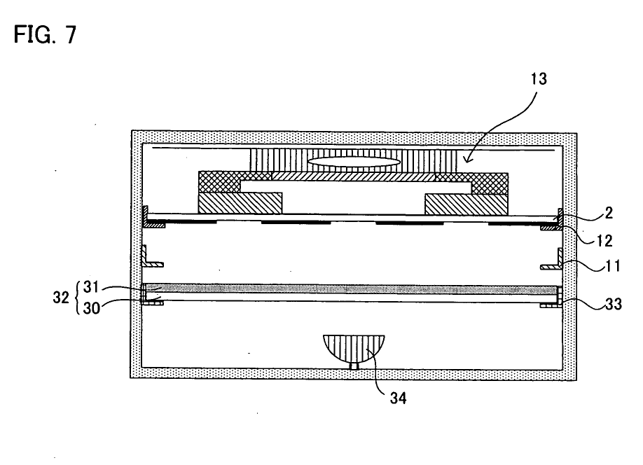

The photocatalyst acting means for using the action of a photocatalyst accompanying energy radiation to remove the foreign matter deposited to the photomask may be means, as illustrated in FIG. 7, a photocatalyst containing layer side substrate supporting section 33 for supporting a photocatalyst containing layer side substrate 32 having: a base material 30, and a photocatalyst containing layer 31 formed on the base material 30 and containing at least a photocatalyst; and an energy radiating section 34 for radiating energy to the photocatalyst containing layer 31 of the photocatalyst containing layer side substrate 32. The photocatalyst containing layer side substrate supporting section is not particularly limited as long as the section is capable of arranging the photocatalyst containing layer of the photocatalyst containing layer side substrate so as to be opposed to the photomask surface side onto which the foreign matter is deposited. The shape, raw material and other properties of this photocatalyst containing layer side substrate supporting section may be identical with those of the pattern forming substrate supporting section, which will be detailed later. This pattern forming substrate supporting section itself can be used as the photocatalyst containing layer side substrate supporting section. The photocatalyst containing layer side substrate used in this case may be the same as described in the sub-item “Foreign matter removing step” in the item “A. Manufacturing method of a plurality of pattern formed bodies”.

The above-mentioned energy radiating section is not particularly limited as long as the section is capable of radiating energy making it possible to activate the photocatalyst contained in the photocatalyst containing layer side substrate and remove the foreign matter deposited to the photomask by action of the photocatalyst. A light source used in this energy radiating section may be selected from a mercury lamp, a metal halide lamp, a xenon lam, an excimer lamp, and other various lamps. The energy radiating section may be means which can emit an excimer laser, a YAG laser, or some other laser. In order to improve the sensitivity of the photocatalyst, the section may have a temperature adjusting section for heating the photocatalyst containing layer. The method for radiating energy in this photocatalyst acting means may be the same as described in the sub-item “Foreign matter removing step” in the item “A. Manufacturing method of a plurality of pattern formed bodies”.

2. Pattern Forming Substrate Supporting Section

Next, the pattern forming substrate supporting section in the pattern formed body manufacturing apparatus of the invention is described herein. This substrate supporting section is not particularly limited as long as the section is capable of supporting the pattern forming substrate stably inside the pattern formed body manufacturing apparatus. The shape and other properties of this substrate supporting section are appropriately selected in accordance with the shape, the usage and other properties of the pattern forming substrate exposed to light by means of the pattern formed body manufacturing apparatus of the invention. Thus, the substrate supporting section may have, for example, a structure capable of supporting the whole of the pattern forming substrate, or a structure capable of supporting one or more portions of the pattern forming substrate.

About this pattern forming substrate supporting section, the raw material and other properties thereof are not particularly limited as long as the section has a strength making it possible to support the pattern forming substrate. For example, the raw material may be an inorganic material such as a metal or a ceramic, or an organic material such as a plastic. The pattern forming substrate supported on the pattern forming substrate supporting section may be the same as described in the above-mentioned item “A. Manufacturing method of a plurality of pattern formed bodies”.

3. Photomask Supporting Section

Next, the photomask supporting section in the pattern formed body manufacturing apparatus of the invention is described herein. This photomask supporting section is not particularly limited as long as the section is capable of supporting the photomask stably in the pattern formed body manufacturing apparatus so as to be opposed to the pattern forming substrate supported on the pattern forming substrate supporting section. The shape and other properties of this photomask supporting section are appropriately selected in accordance with the shape, the usage and other properties of the photomask. Thus, this section may have, for example, a structure capable of supporting the whole of the photomask, or a structure capable of supporting one or more portions of the photomask.

This photomask supporting section may be identical with the above-mentioned pattern forming substrate supporting section. The photomask supporting section and the pattern forming substrate supporting section are formed in such a manner that the pattern forming substrate and the photomask are supported so as to have, therebetween, such a distance that the action of vacuum-ultraviolet light can be given to the pattern forming substrate. The distance and the photomask supported on the photomask supporting section may be the same as described in the above-mentioned item “A. Manufacturing method of a plurality of pattern formed bodies”.

4. Vacuum-Ultraviolet Light Radiating Section

Next, the vacuum-ultraviolet light radiating section used in the invention is described herein. This section is not particularly limited as long as the section is capable of radiating vacuum-ultraviolet light to the pattern forming substrate. As illustrated in FIG. 2A, in the pattern formed body manufacturing apparatus, this vacuum-ultraviolet light radiating section may be, for example, a section having a light source 40 capable of radiating vacuum-ultraviolet light, a lamp house 41 in which the light source 40 is put, a lamp house holder 43 which holds the lamp house 41 and has a quartz window 42, and a chamber 44 fitted to the lamp house holder 43. The vacuum-ultraviolet light radiated from the light source 40 may be vacuum-ultraviolet light which permeates through the quartz window 42, passes through a cavity portion 45 in the lamp house holder 43 and the chamber 44, and then reaches the photomask supported on the photomask supporting section. Usually, the cavity portion 45 is filled with gas which hardly absorbs the vacuum-ultraviolet light, such as nitrogen, or is made into a high-level vacuum. The lamp house, the quartz window, the lamp house holder, and the chamber may be the same as used in an ordinary vacuum-ultraviolet light radiating device. As illustrated in FIG. 2A, the vacuum-ultraviolet light radiating section may be arranged at the side of the photomask supporting section 12.

The wavelength of the vacuum-ultraviolet light radiated from this vacuum-ultraviolet light radiating section is set usually into the range of 100 to 250 nm, preferably into the range of 150 to 200 nm.

A light source capable of radiating vacuum-ultraviolet light having such a wavelength can be selected from an excimer lamp, a low-pressure mercury lamp, and other various light sources.

5. Pattern Formed Body Manufacturing Apparatus

The pattern formed body manufacturing apparatus of the invention is not particularly limited as long as the apparatus has the above-mentioned foreign matter removing means, pattern forming substrate supporting section, photomask supporting section and vacuum-ultraviolet light radiating section. If necessary, the apparatus may have, for example, temperature controlling means for controlling the temperature of the inside of this pattern formed body manufacturing apparatus, humidity controlling means for controlling the humidity of the inside of this apparatus, or some other means.

The invention is not limited to the above-mentioned embodiments. Any modification that has substantially the same structure as these embodiments, which embody the technical conception recited in the claims of the invention, and that produces the same advantageous effects as the embodiments is included in the technical scope of the invention.

### EXAMPLES

### Example 1

<Production of a Pattern Forming Substrate>

At room temperature, 1.5 g of a fluoroalkylsilane (TSL 8233, manufactured by GE Toshiba Silicone Co., Ltd.), 5.0 g of a tetramethoxysilane (TSL 8114, manufactured by GE Toshiba Silicone Co., Ltd.), and 3 g of 0.1 N hydrochloric acid were stirred for 24 hours to produce a liquid repellent agent containing fluorine. To 1 g of this liquid repellent agent was added 99 g of isopropanol, and then the solution was stirred at room temperature for 10 minutes. This diluted solution was coated onto a glass substrate with a spin coater (at 700 rpm for 5 seconds) to yield a pattern forming substrate on which a wettability variable layer having liquid repellency was formed.

<Pattern-Forming Step>

The pattern forming substrate and a photomask having a pattern with alternately-arranged lines and spaces each having a line width of 20 μm were opposed to each other so as to have an interval of 1 μm therebetween, and an excimer lamp was used to radiate vacuum-ultraviolet light through the photomask onto the pattern forming substrate for 100 seconds. As a result, a line pattern, as a lyophilic area, in which its line widths were each 20 μm was formed.

<Foreign Matter Removing Step and Pattern-Forming Step>

Subsequently, as a foreign matter removing step, the following was performed: the photomask and the pattern forming substrate were allowed to stand still for 10 minutes in the state that these were apart 10 cm or more from each other. This period of 10 minutes was a leaving period decided in a leaving period deciding step, in which line widths of a line pattern as a lyophilic area were measured, before the above-mentioned pattern-forming step. Thereafter, in a subsequent pattern-forming step, vacuum-ultraviolet light was radiated through the photomask, which underwent the above-mentioned foreign matter removing step, onto the same pattern forming substrate as described above for 100 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 20 μm. The line widths of the line pattern as the lyophilic area were measured by observing the surface of each of the pattern formed bodies with an optical microscope.

### Example 2

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 50 μm were opposed to each other so as to have an interval of 10 μm therebetween, and an excimer lamp was used to radiate vacuum-ultraviolet light through the photomask onto the pattern forming substrate for 40 seconds. As a result, a line pattern, as a lyophilic area, in which its line widths were each 50 μm was formed.

<Foreign Matter Removing Step and Pattern-Forming Step>

Subsequently, the following was performed as a foreign matter removing step: the surface side of the exposed photomask which was opposed to the pattern forming substrate was sucked under a pressure of 100 mmHg for 3 minutes. Thereafter, in a subsequent pattern-forming step, vacuum-ultraviolet light was radiated through the photomask, which underwent the above-mentioned foreign matter removing step, onto the same pattern forming substrate as described above for 40 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 50 μm. The line widths of the line pattern as the lyophilic area were measured by observing the surface of each of the pattern formed bodies with an optical microscope.

### Example 3

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 15 μm were opposed to each other so as to have an interval of 2 μm therebetween, and an excimer lamp was used to radiate vacuum-ultraviolet light through the photomask onto the pattern forming substrate for 90 seconds. As a result, a line pattern, as a lyophilic area, in which its line widths were each 15 μm was formed.

<Foreign Matter Removing Step and Pattern-Forming Step>

Subsequently, the following was performed as a foreign matter removing step: wind having a wind speed of 8.5 m/second (measured with a vane type anemometer in a measurement range of 4 inches) was blown, for 4 minutes, onto the surface side of the exposed photomask which was opposed to the pattern forming substrate. Thereafter, in a subsequent pattern-forming step, vacuum-ultraviolet light was radiated through the photomask, which underwent the above-mentioned foreign matter removing step, onto the same pattern forming substrate as described above for 90 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 15 μm. The line widths of the line pattern as the lyophilic area were measured by observing the surface of each of the pattern formed bodies with an optical microscope.

### Example 4

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 40 μm were opposed to each other so as to have an interval of 5 μm therebetween, and an excimer lamp was used to radiate vacuum-ultraviolet light through the photomask onto the pattern forming substrate for 60 seconds. As a result, a line pattern, as a lyophilic area, in which its line widths were each 40 μm was formed.

<Foreign Matter Removing Step and Pattern-Forming Step>

Subsequently, the following was performed as a foreign matter removing step: the surface side of the exposed photomask which was opposed to the pattern forming substrate was subjected to spray washing with a 50% solution of methanol in water as a washing solution at a jetting-out amount of 1 L/min. under a jetting-out pressure of 1 MPa for 30 seconds, and then air was blown onto the surface side to remove the washing solution adhered to the photomask completely. Thereafter, in a subsequent pattern-forming step, vacuum-ultraviolet light was radiated through the photomask, which underwent the above-mentioned foreign matter removing step, onto the same pattern forming substrate as described above for 60 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 40 μm. The line widths of the line pattern as the lyophilic area were measured by observing the surface of each of the pattern formed bodies with an optical microscope.

### Example 5

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 50 μm were opposed to each other so as to have an interval of 10 μm therebetween, and an excimer lamp was used to radiate vacuum-ultraviolet light through the photomask onto the pattern forming substrate for 40 seconds. As a result, a line pattern, as a lyophilic area, in which its line widths were each 50 μm was formed.

<Foreign Matter Removing Step and Pattern-Forming Step>

Subsequently, the following was performed as a foreign matter removing step: water vapor having a temperature of 120° C. was sprayed onto the surface side of the exposed photomask which was opposed to the pattern forming substrate for 2 minutes, and then air was blown onto the surface side to remove the water vapor adhered to the photomask completely. Thereafter, in a subsequent pattern-forming step, vacuum-ultraviolet light was radiated through the photomask, which underwent the above-mentioned foreign matter removing step, onto the same pattern forming substrate as described above for 40 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 50 μm. The line widths of the line pattern as the lyophilic area were measured by observing the surface of each of the pattern formed bodies with an optical microscope.

### Example 6

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 30 μm were opposed to each other so as to have an interval of 5 μm therebetween, and an excimer lamp was used to radiate vacuum-ultraviolet light through the photomask onto the pattern forming substrate for 60 seconds. As a result, a line pattern, as a lyophilic area, in which its line widths were each 30 μm was formed.

<Foreign Matter Removing Step and Pattern-Forming Step>

Subsequently, the following was performed as a foreign matter removing step: an adsorbing plate made of silicone rubber was brought into contact with the surface side of the exposed photomask which was opposed to the pattern forming substrate under a closely-adhesive pressure of 1.2 kg/cm² for 20 seconds. Thereafter, in a subsequent pattern-forming step, vacuum-ultraviolet light was radiated through the photomask, which underwent the above-mentioned foreign matter removing step, onto the same pattern forming substrate as described above for 60 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 30 μm. The line widths of the line pattern as the lyophilic area were measured by observing the surface of each of the pattern formed bodies with an optical microscope.

### Example 7

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 60 μm were opposed to each other so as to have an interval of 10 μm therebetween, and an excimer lamp was used to radiate vacuum-ultraviolet light through the photomask onto the pattern forming substrate for 40 seconds. As a result, a line pattern, as a lyophilic area, in which its line widths were each 60 μm was formed.

<Foreign Matter Removing Step and Pattern-Forming Step>

Subsequently, the following was performed as a foreign matter removing step: the surface side of the exposed photomask which was opposed to the pattern forming substrate was heated with a hot plate having a temperature of 80° C. for 2 minutes, and then air having room temperature was blown onto the surface side to return the temperature of the photomask to room temperature. Thereafter, in a subsequent pattern-forming step, vacuum-ultraviolet light was radiated through the photomask, which underwent the above-mentioned foreign matter removing step, onto the same pattern forming substrate as described above for 40 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 60 μm. The line widths of the line pattern as the lyophilic area were measured by observing the surface of each of the pattern formed bodies with an optical microscope.

### Example 8

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 40 μm were opposed to each other so as to have an interval of 5 μm therebetween, and an excimer lamp was used to radiate vacuum-ultraviolet light through the photomask onto the pattern forming substrate for 60 seconds. As a result, a line pattern, as a lyophilic area, in which its line widths were each 40 μm was formed.

<Foreign Matter Removing Step and Pattern-Forming Step>

Subsequently, the following was performed as a foreign matter removing step: atmospheric pressure oxygen plasma was radiated to the surface side of the exposed photomask which was opposed to the pattern forming substrate at an electric power of 700 W, a radiation distance of 5 mm and a processing speed of 20 mm/sec. Thereafter, in a subsequent pattern-forming step, vacuum-ultraviolet light was radiated through the photomask, which underwent the above-mentioned foreign matter removing step, onto the same pattern forming substrate as described above for 60 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 40 μm. The line widths of the line pattern as the lyophilic area were measured by observing the surface of each of the pattern formed bodies with an optical microscope.

### Example 9

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 50 μm were opposed to each other so as to have an interval of 10 μm therebetween, and an excimer lamp was used to radiate vacuum-ultraviolet light through the photomask onto the pattern forming substrate for 40 seconds. As a result, a line pattern, as a lyophilic area, in which its line widths were each 50 μm was formed.

<Foreign Matter Removing Step and Pattern-Forming Step>

Subsequently, the following was performed as a foreign matter removing step: an electron beam radiating device of an electron curtain type was used to radiate an electron beam to the surface side of the exposed photomask which was opposed to the pattern forming substrate at acceleration energy of 10 Mrad. Thereafter, in a subsequent pattern-forming step, vacuum-ultraviolet light was radiated through the photomask, which underwent the above-mentioned foreign matter removing step, onto the same pattern forming substrate as described above for 40 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 50 μm. The line widths of the line pattern as the lyophilic area were measured by observing the surface of each of the pattern formed bodies with an optical microscope.

### Example 10

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 20 μm were opposed to each other so as to have an interval of 1 μm therebetween, and an excimer lamp was used to radiate vacuum-ultraviolet light through the photomask onto the pattern forming substrate for 100 seconds. As a result, a line pattern, as a lyophilic area, in which its line widths were each 20 μm was formed.

<Foreign Matter Removing Step and Pattern-Forming Step>

Subsequently, the following was performed as a foreign matter removing step: minus ions and plus ions were simultaneously radiated to the surface side of the exposed photomask which was opposed to the pattern forming substrate from a position having a radiation distance of 5 cm at an ion balance of ±5V and a generated ion number of 100000 to 500000 per milliliter for 3 minutes. Thereafter, in a subsequent pattern-forming step, vacuum-ultraviolet light was radiated through the photomask, which underwent the above-mentioned foreign matter removing step, onto the same pattern forming substrate as described above for 100 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 20 μm. The line widths of the line pattern as the lyophilic area were measured by observing the surface of each of the pattern formed bodies with an optical microscope.

### Example 11

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 30 μm were opposed to each other so as to have an interval of 5 μm therebetween, and an excimer lamp was used to radiate vacuum-ultraviolet light through the photomask onto the pattern forming substrate for 60 seconds. As a result, a line pattern, as a lyophilic area, in which its line widths were each 30 μm was formed.

<Foreign Matter Removing Step and Pattern-Forming Step>

Subsequently, the following was performed as a foreign matter removing step: the vacuum-ultraviolet light was radiated for 2 minutes using an excimer lamp to the side of the photomask after the exposure which is opposite to the pattern forming substrate. Thereafter, in a subsequent pattern-forming step, vacuum-ultraviolet light was radiated through the photomask, which underwent the above-mentioned foreign matter removing step, onto the above-mentioned pattern forming substrate for 60 seconds.

The same foreign matter removing step and pattern-forming step as described above were alternately repeated to manufacture 100 pattern formed bodies. As a result, a line pattern, as a lyophilic area, in each of the 100 pattern formed bodies was able to be formed to have line widths of 30 μm. The line widths of the line pattern as the lyophilic area were measured by observing the surface of each of the pattern formed bodies with an optical microscope.

### Comparative Example 1

<Production of a Pattern Forming Substrate>

In the same way as in Example 1, a pattern forming substrate in which a wettability variable layer having liquid repellency was formed was produced.

<Pattern-Forming Step>

The pattern forming substrate and a photomask having a pattern with alternately-arranged lines and spaces each having a line width of 50 μm were opposed to each other so as to have an interval of 10 μm therebetween, and an excimer lamp was used to radiate vacuum-ultraviolet light through the photomask onto the pattern forming substrate for 40 seconds. As a result, a line pattern, as a lyophilic area, in which its line widths were each 50 μm was formed.

Immediately after the exposure to the light, the exposed pattern forming substrate was exchanged for an unexposed pattern forming substrate and then vacuum-ultraviolet light was radiated thereto in the same way as described above for 40 seconds while the photomask was fixed to the predetermined position.

Only the same pattern forming step as described above was continuously performed to manufacture 100 pattern formed bodies. As a result, in the first one out of the 100 pattern formed bodies, a line pattern as a lyophilic area in which its line widths were each 50 μm was formed. However, in the second one, a line pattern as a lyophilic area in which its line widths were each 53 μm was formed. In the third one and ones formed later, their line widths tended to become larger. In the seventh one and ones formed later, their entire surfaces became lyophilic. Thus, the ink got wet and spread to the entire surface of their substrates, so that no pattern was formed.

What is claimed is:

1. A manufacturing method of a plurality of pattern formed bodies comprising a pattern forming step and a foreign matter removing step,
Wherein the pattern forming step is a step of radiating vacuum-ultraviolet light through a photomask to a pattern forming substrate, varying a surface property by the vacuum-ultraviolet light, and forming a property varied pattern with the property varied on a surface of the pattern forming substrate to form a pattern formed body;
the pattern forming step is repeated plural times to manufacture a plurality of the pattern formed bodies; and
the foreign matter removing step is a step of removing a foreign matter deposited to the photomask performed between the repeated pattern forming steps.

2. The manufacturing method of the pattern formed bodies according to claim 1,
wherein a leaving period deciding step of deciding a period when the photomask is to be left as it is is further comprised, and
the foreign matter removing step is a step of leaving the photomask as it is in the period decided in the leaving period deciding step to remove the foreign matter deposited to the photomask.

3. The manufacturing method of the pattern formed bodies according to claim 1, wherein the foreign matter removing step is a step of suctioning and removing the foreign matter deposited to the photomask surface.

4. The manufacturing method of the pattern formed bodies according to claim 1, wherein the foreign matter removing step is a step of removing the foreign matter deposited to the photomask surface by wind pressure.

5. The manufacturing method of the pattern formed bodies according to claim 1, wherein the foreign matter removing step is a step of washing the foreign matter deposited to the photomask surface with a liquid.

6. The manufacturing method of the pattern formed bodies according to claim 1, wherein the foreign matter removing step is a step of removing the foreign matter deposited to the photomask surface by action of water vapor.

7. The manufacturing method of the pattern formed bodies according to claim 1, wherein the foreign matter removing step is a step of adsorbing and removing the foreign matter deposited to the photomask surface by an adsorbing plate.

8. The manufacturing method of the pattern formed bodies according to claim 1, wherein the foreign matter removing step is a step of radiating thermal energy to the photomask to remove the foreign matter deposited to the photomask surface.

9. The manufacturing method of the pattern formed bodies according to claim 1, wherein the foreign matter removing step is a step of radiating plasma to the photomask to remove the foreign matter deposited to the photomask surface.

10. The manufacturing method of the pattern formed bodies according to claim 1, wherein the foreign matter removing step is a step of radiating an electron beam to the photomask to remove the foreign matter deposited to the photomask surface.

11. The manufacturing method of the pattern formed bodies according to claim 1, wherein the foreign matter removing step is a step of radiating a positively- and/or negatively-charged ion to the photomask to remove the foreign matter deposited to the photomask surface.

12. The manufacturing method of the pattern formed bodies according to claim 1, wherein the foreign matter removing step is a step of:
preparing a photocatalyst containing layer side substrate comprising a base material and a photocatalyst containing layer formed on the base material and containing at least a photocatalyst;
arranging a surface of the photomask with the foreign matter deposited and the photocatalyst containing layer of the photocatalyst containing side substrate to oppose to each other; and
radiating energy to the photocatalyst containing layer to remove the foreign matter deposited to the photomask surface.

13. A pattern formed body manufacturing apparatus used at the time of manufacturing a plurality of pattern formed bodies,
wherein the pattern formed bodies are manufactured by repeating plural times a pattern forming step which is a step of radiating vacuum-ultraviolet light through a photomask to a pattern forming substrate, varying a surface property by the vacuum-ultraviolet light, and forming a property varied pattern with the property varied on a surface of the pattern forming substrate to form a pattern formed body; and
the apparatus comprises: a pattern forming substrate supporting section for supporting the pattern forming substrate, a photomask supporting section for supporting the photomask to be oppose to the pattern forming substrate, a vacuum-ultraviolet light radiating section for radiating the vacuum-ultraviolet light to the pattern forming substrate, and foreign matter removing means for removing a foreign matter deposited to the photomask.

14. The pattern formed body manufacturing apparatus according to claim 13, wherein the foreign matter removing means is suctioning means for suctioning the foreign matter deposited to the photomask.

15. The pattern formed body manufacturing apparatus according to claim 13, wherein the foreign matter removing means is gas blowing means for removing the foreign matter by wind pressure.

16. The pattern formed body manufacturing apparatus according to claim 13, wherein the foreign matter removing means is washing means for washing the photomask with a liquid.

17. The pattern formed body manufacturing apparatus according to claim 13, wherein the foreign matter removing means is water vapor acting means for removing the foreign matter deposited to the photomask by action of water vapor.

18. The pattern formed body manufacturing apparatus according to claim 13, wherein the foreign matter removing means is adsorbing means for contacting an adsorbing plate with the photomask to remove the foreign matter.

19. The pattern formed body manufacturing apparatus according to claim 13, wherein the foreign matter removing means is thermal energy radiating means for radiating thermal energy to the photomask.

20. The pattern formed body manufacturing apparatus according to claim 13, wherein the foreign matter removing means is ion radiating means for radiating a positively- and/or negatively-charged ion to the photomask.

21. The pattern formed body manufacturing apparatus according to claim 13, wherein the foreign matter removing means is photocatalyst acting means for removing the foreign matter deposited to the photomask by action of a photocatalyst accompanying energy radiation.
